(19) United States
(12) Patent Application Publication
(10) Pub. No.: US 2023/0184498 A1
(43) Pub. Date: Jun. 15, 2023

(54) IMMERSION-TYPE HEAT DISSIPATION SUBSTRATE HAVING MICROPOROUS STRUCTURE

(71) Applicant: AMULAIRE THERMAL TECHNOLOGY, INC., New Taipei City (TW)

(72) Inventors: CHENG-SHU PENG, New Taipei City (TW); TZE-YANG YEH, New Taipei City (TW)

(21) Appl. No.: 17/549,871

(22) Filed: Dec. 14, 2021

(51) Int. Cl. F28F 13/00

(52) U.S. Cl. CPC F28F 13/003

(57) ABSTRACT

An immersion-type heat dissipation substrate having a microporous structure is provided. The immersion-type heat dissipation substrate includes a surface having a plurality of micropores for facilitating generation of vapor bubbles. A pore diameter of each of the plurality of micropores is between 5 μm and 150 μm, and the plurality of micropores cover 3% to 40% of an area of the surface.

### FIELD OF THE DISCLOSURE

The present disclosure relates to a heat dissipation substrate, and more particularly to an immersion-type heat dissipation substrate having a microporous structure.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type heat dissipation substrate having a microporous structure.

In one aspect, the present disclosure provides an immersion-type heat dissipation substrate having a microporous structure, which includes a surface having a plurality of micropores for facilitating generation of vapor bubbles. A pore diameter of each of the plurality of micropores is between 5 μm and 150 μm, and the plurality of micropores cover 3% to 40% of an area of the surface.

In certain embodiments, the pore diameter of each of the plurality of micropores is further defined to be between 10 μm and 40 μm, and the plurality of micropores cover 20% to 30% of the area of the surface.

In certain embodiments, the plurality of micropores are formed on the surface by sintering of metal powder.

In certain embodiments, the plurality of micropores are formed on the surface by laser ablation.

In certain embodiments, the plurality of micropores are formed on the surface by computer numerical control (CNC) machining.

In certain embodiments, the plurality of micropores are formed on the surface by stamping.

Therefore, in the immersion-type heat dissipation substrate having the microporous structure provided by the present disclosure, by virtue of “the surface having the plurality of micropores for facilitating the generation of vapor bubbles”, “the pore diameter of each of the plurality of micropores being between 5 μm and 150 μm”, and “the plurality of micropores covering 3% to 40% of the area of the surface,” the generation of vapor bubbles is accelerated and the vapor bubbles are not trapped in the micropores. Accordingly, the vapor bubbles can be easily removed for heat transfer, thereby improving an overall heat dissipation capacity of the immersion-type heat dissipation substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of an immersion-type heat dissipation substrate of the present disclosure;

FIG. 2 is a scanning electron microscopic photograph showing a surface of the immersion-type heat dissipation substrate according to one embodiment of the present disclosure;

FIG. 3 is a scanning electron microscopic photograph showing a surface of the immersion-type heat dissipation substrate according to one embodiment of the present disclosure;

FIG. 4 is a scanning electron microscopic photograph showing a surface of the immersion-type heat dissipation substrate according to one embodiment of the present disclosure;

FIG. 5 is a scanning electron microscopic photograph showing a surface of the immersion-type heat dissipation substrate according to one embodiment of the present disclosure;

FIG. 6 is a scanning electron microscopic photograph showing a surface of the immersion-type heat dissipation substrate according to one embodiment of the present disclosure; and

FIG. 7 is a scanning electron microscopic photograph showing a surface of the immersion-type heat dissipation substrate according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

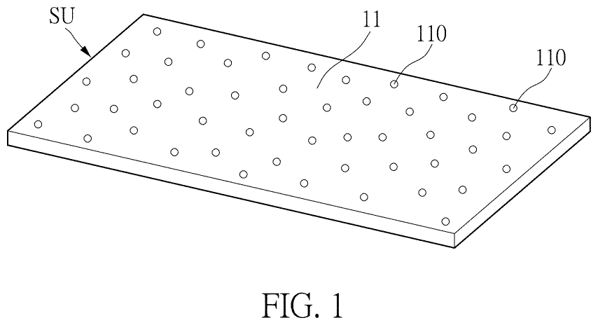

Referring to FIG. 1, one particular embodiment of the present disclosure is shown. The present embodiment provides an immersion-type heat dissipation substrate having a microporous structure (hereinafter referred to as an immersion-type heat dissipation substrate SU) that can be used for contacting a heat producing element.

In the present embodiment, the immersion-type heat dissipation substrate SU is exemplarily an immersion-type heat sink of any size and can be immersed in a two-phase coolant. Moreover, to improve a heat dissipation capacity of the immersion-type heat sink, utilizing a plurality of micropores 110 on a surface 11 thereof to accelerate generation and removal of vapor bubbles can be the most effective approach. However, the vapor bubbles can be trapped in the micropores 110 when the micropores 110 are too small in size, such that the vapor bubbles cannot be easily removed for heat transfer. On the other hand, the micropores 110 being too large can adversely affect the generation of vapor bubbles. Accordingly, a maximum pore diameter (or an effective diameter) of the micropore 110 is at least between 5 μm and 150 μm. It should be noted that the plurality of micropores 110 are exaggeratedly enlarged in FIG. 1 for a better understanding of the present disclosure.

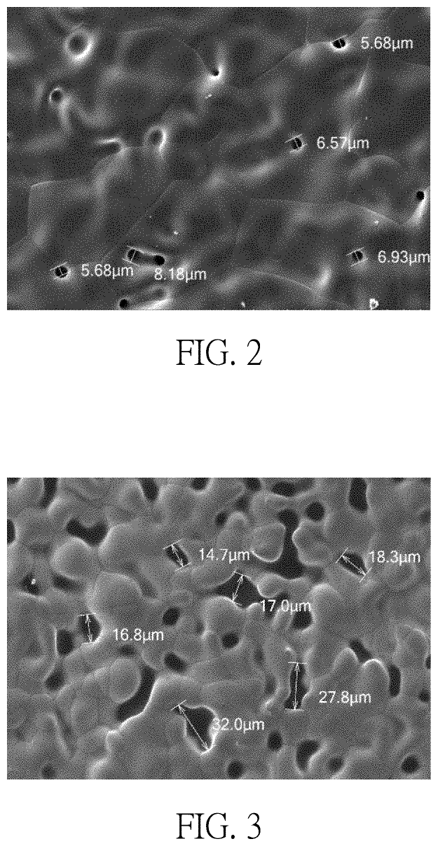

Referring to FIG. 2, FIG. 2 is a scanning electron microscopic photograph showing a surface of the immersion-type heat dissipation substrate according to one embodiment of the present disclosure. As shown in FIG. 2, the pore diameter of each of the plurality of micropores is between 5 μm and 10 μm. Moreover, when the pore diameter of each of the plurality of micropores is between 5 μm and 10 μm as shown in FIG. 2, and power of the heat producing element is 200 watts, a measured thermal resistance (i.e., a ratio of a temperature change of the immersion-type heat dissipation substrate to heat energy generated by the heat producing element) of the immersion-type heat dissipation substrate is 0.0603. When the power of the heat producing element is 300 watts, the measured thermal resistance of the immersion-type heat dissipation substrate is 0.0510, such that the thermal resistance of the immersion-type heat dissipation substrate is reduced and the heat dissipation capacity of the immersion-type heat dissipation substrate is increased.

Referring to FIG. 3, FIG. 3 is a scanning electron microscopic photograph showing a surface of the immersion-type heat dissipation substrate according to one embodiment of the present disclosure. As shown in FIG. 3, the pore diameter of each of the plurality of micropores is between 10 μm and 40 μm. Moreover, when the pore diameter of each of the plurality of micropores is between 10 μm and 40 μm as shown in FIG. 3, and the power of the heat producing element is 200 watts, the measured thermal resistance of the immersion-type heat dissipation substrate is 0.0477. When the power of the heat producing element is 300 watts, the measured thermal resistance of the immersion-type heat dissipation substrate is 0.0438.

Based on results of actual testing described above, when the power of the heat producing element is 200 watts, the measured thermal resistance of the immersion-type heat dissipation substrate is reduced from 0.0603 to 0.0477, and the heat dissipation capacity thereof is improved by 20.9%. When the power of the heat producing element is 300 watts, the measured thermal resistance of the immersion-type heat dissipation substrate is reduced from 0.0510 to 0.0438, and the heat dissipation capacity of the immersion-type heat dissipation substrate is improved by 14.1%. Accordingly, when the pore diameter of each the plurality of micropores on the surface of the immersion-type heat dissipation substrate is between 10 μm and 40 μm, the thermal resistance of the immersion-type heat dissipation substrate is greatly reduced and the heat dissipation capacity of the immersion-type heat dissipation substrate is significantly improved.

Furthermore, the heat dissipation capacity of the immersion-type heat dissipation substrate can be substantially improved through a cooperation of the pore diameter of each of the plurality of micropores and an area covered by the plurality of micropores on the surface of the immersion-type heat dissipation substrate.

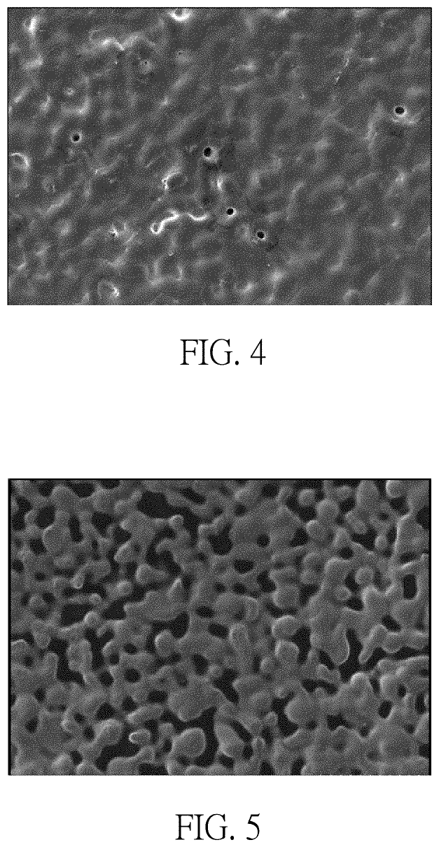

Referring to FIG. 4, FIG. 4 is a scanning electron microscopic photograph showing a surface of the immersion-type heat dissipation substrate according to one embodiment of the present disclosure. As shown in FIG. 4, the plurality of micropores cover 5% of the area of the surface.

Referring to FIG. 5, FIG. 5 is a scanning electron microscopic photograph showing a surface of the immersion-type heat dissipation substrate according to one embodiment of the present disclosure. As shown in FIG. 5, the plurality of micropores cover 10% of the area of the surface.

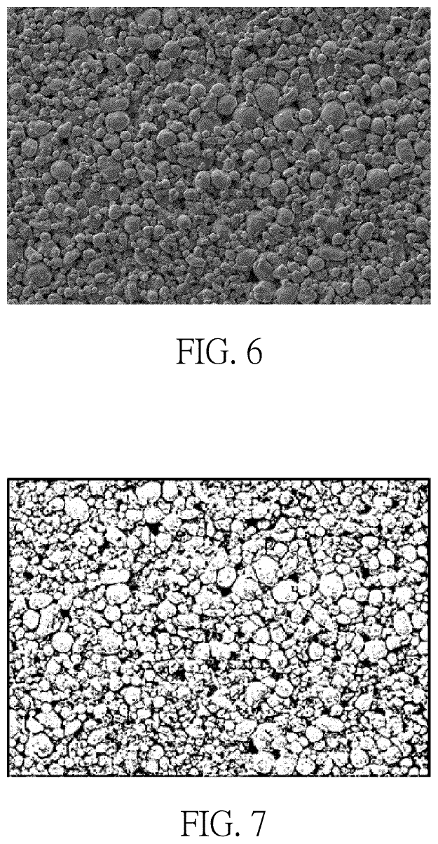

Referring to FIG. 6, FIG. 6 is a scanning electron microscopic photograph showing a surface of the immersion-type heat dissipation substrate according to one embodiment of the present disclosure. As shown in FIG. 6, the plurality of micropores cover 20% of the area of the surface.

Referring to FIG. 7, FIG. 7 is a scanning electron microscopic photograph showing a surface of the immersion-type heat dissipation substrate according to one embodiment of the present disclosure. As shown in FIG. 7, the plurality of micropores cover 27.8% of the area of the surface.

Therefore, in the present embodiment, the plurality of micropores 110 of the immersion-type heat dissipation substrate SU cover at least 3% to 40% of the area of the surface 11. That is to say, the plurality of micropores 110 occupy 3% to 40% of the area of the surface 11. Moreover, when the plurality of micropores 110 occupy 20% to 30% of the area of the surface 11, the heat dissipation capacity of the immersion-type heat dissipation substrate SU can be effectively improved.

In addition, in the present embodiment, the plurality of micropores 110 on the surface 11 of the immersion-type heat dissipation substrate SU can be formed on the surface 11 of the immersion-type heat dissipation substrate SU by a process of sintering metal powder. In another embodiment, the plurality of micropores 110 on the surface 11 of the immersion-type heat dissipation substrate SU can be formed on the surface 11 of the immersion-type heat dissipation substrate SU by laser ablation. Furthermore, the plurality of micropores 110 on the surface 11 of the immersion heat dissipation substrate SU can also be formed on the surface 11 of the immersion-type heat dissipation substrate SU by computer numerical control (CNC) machining or stamping.

### Beneficial Effects of the Embodiments

In conclusion, in the immersion-type heat dissipation substrate having the microporous structure provided by the present disclosure, by virtue of “the surface having the plurality of micropores for facilitating the generation of vapor bubbles”, “the pore diameter of each of the plurality of micropores being between 5 μm and 150 μm”, and “the plurality of micropores covering 3% to 40% of the area of the surface,” the generation of vapor bubbles is accelerated and the vapor bubbles are not trapped in the micropores. Accordingly, the vapor bubbles can be easily removed for heat transfer, thereby improving an overall heat dissipation capacity of the immersion-type heat dissipation substrate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion-type heat dissipation substrate having a microporous structure, comprising:
a surface having a plurality of micropores for facilitating generation of vapor bubbles;
wherein a pore diameter of each of the plurality of micropores is between 5 μm and 150 μm, and the plurality of micropores cover 3% to 40% of an area of the surface.

2. The immersion-type heat dissipation substrate according to claim 1, wherein the pore diameter of each of the plurality of micropores is further defined to be between 10 μm and 40 μm, and the plurality of micropores cover 20% to 30% of the area of the surface.

3. The immersion-type heat dissipation substrate according to claim 2, wherein the plurality of micropores are formed on the surface by sintering of metal powder.

4. The immersion-type heat dissipation substrate according to claim 2, wherein the plurality of micropores are formed on the surface by laser ablation.

5. The immersion-type heat dissipation substrate according to claim 2, wherein the plurality of micropores are formed on the surface by computer numerical control (CNC) machining.

6. The immersion-type heat dissipation substrate according to claim 2, wherein the plurality of micropores are formed on the surface by stamping.
